(19) United States
(12) Patent Application Publication
(10) Pub. No.: US 2026/0276696 A1
(43) Pub. Date: Sep. 17, 2026

(54) TESTING CIRCUIT FOR ACCURATE TRANSISTOR LEAKAGE CURRENT MEASUREMENTS

(71) Applicant: TEXAS INSTRUMENTS INCORPORATED, Dallas, TX (US)

(72) Inventors: Jordan Herschell Wenske, Richardson, TX (US); David Hernandez, Fort Worth, TX (US); Brian Elies, Dallas, TX (US); Erkan Bilhan, Dallas, TX (US); Francisco A. Cano, Sugar Land, TX (US)

(21) Appl. No.: 19/423,942

(22) Filed: Dec. 17, 2025

Related U.S. Application Data
(60) Provisional application No. 63/771,974, filed on Mar. 14, 2025.

(51) Int. Cl. G01R 31/26; H03K 17/687; H03F 3/45

(52) U.S. Cl. CPC G01R 31/2607; H03K 17/6871; H03F 3/45475

(57) ABSTRACT

A circuit comprises an amplifier, a first transistor, a second transistor, a set of transistors, a first and second switch, a component circuitry, and a control circuit. The first and second transistors, and the set of transistors include a first current terminal, a second current terminal, and a control terminal, respectively. The first current terminal of the second transistor is coupled to the first current terminal of the first transistor, and the control terminal of the second transistor is coupled to the control terminal of the first transistor. The first current terminal of the set of transistors is coupled to the control terminal of the set of transistors. A first current terminal of the first switch is coupled to the input of the amplifier, and the second terminal of the first switch is coupled to the second current terminal of the set of transistors.

### REFERENCE TO RELATED APPLICATION

This application claims priority to and the benefit of U.S. Provisional Application Serial No. 63/771,974 which was filed March 14, 2025, entitled “Analog Front-End for Accurate Transistor Leakage Current Measurements”, the entirety of which is hereby incorporated by reference as if fully set forth herein.

### BACKGROUND

An integrated circuit (IC) can be a semiconductor device that includes interconnected devices such as transistors, diodes, resistors, capacitors, processors, or other component circuitry that function together, enabling the IC to perform various tasks. Such tasks, for example, can include controlling an electronic device or performing logic operations particular to that device. Upon manufacture, a circuit utilizes test structure(s) on the silicon substrate for the measurement and behavior characterization of electrical parameters associated with devices on the IC.

### SUMMARY

In some examples, a circuit comprises an amplifier, a first, second and third transistor. The amplifier includes an output and an input. The first transistor includes a first current terminal, a second current terminal, and a control terminal. The control terminal of the first transistor is coupled to the output of the amplifier. The second transistor includes a current terminal and a control terminal. The current terminal of the second transistor is coupled to the first current terminal of the first transistor, and the control terminal of the second transistor is coupled to the control terminal of the first transistor and to the output of the amplifier. The third transistor includes a first current terminal, a second current terminal and a control terminal. The second current terminal of the third transistor is coupled to the input of the amplifier and to the second current terminal of the first transistor. The control terminal of the third transistor is coupled to the first current terminal of the third transistor.

In some examples, a circuit comprises an amplifier, a first transistor and a second transistor, a set of transistors, a first switch, and a second switch. The amplifier includes an output and an input. The first transistor includes a first current terminal, a second current terminal, and a control terminal. The control terminal of the first transistor is coupled to the output of the amplifier. The second transistor includes a current terminal and a control terminal. The current terminal of the second transistor is coupled to the first current terminal of the first transistor, and the control terminal of the second transistor is coupled to the control terminal of the first transistor and to the output of the amplifier. The set of transistors includes a first current terminal, a second current terminal, and a control terminal, respectively, wherein the first current terminal of the set of transistors is coupled to the control terminal of the set of transistors. The first switch includes a first terminal and a second terminal. The first terminal of the first switch is coupled to the input of the amplifier and the second terminal of the first switch is coupled to the second current terminal of the set of transistors. The second switch includes a first terminal and a second terminal. The first terminal of the second switch is coupled to the second current terminal of the first transistor, and the second terminal of the second switch is coupled to the second current terminal of the first set of transistors.

In some examples, a circuit comprises an amplifier, a first transistor and a second transistor, a set of transistors, a first switch, at least one component circuitry, and a control circuit. The amplifier includes an output and an input. The first transistor includes a first current terminal, a second current terminal, and a control terminal. The second transistor includes a current terminal and a control terminal. The current terminal of the second transistor is coupled to the first current terminal of the first transistor, and the control terminal of the second transistor is coupled to the control terminal of the first transistor. The set of transistors includes a first current terminal, a second current terminal, and a control terminal, respectively. The first current terminal of the set of transistors is coupled to the control terminal of the set of transistors. The first switch includes a first terminal and a second terminal. The first terminal of the first switch is coupled to the input of the amplifier, and the second terminal of the first switch is coupled to the second current terminal of the set of transistors. The at least one component circuitry is coupled to the amplifier or the second transistor via a second switch. The control circuit, coupled to the first switch and the second switch, couples the set of transistors to the amplifier in a test mode of operation from a normal mode of operation and decouples the at least one component circuitry from the amplifier or the second transistor.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a system of a circuit that determines leakage current in a device under test (DUT) in accordance with some examples.

FIG. 2 is a system of a circuit that includes testing circuitry for determining leakage current in a DUT in accordance with some examples.

FIG. 3 is a system of a circuit that includes testing circuitry for determining leakage current in various DUTs of different type in accordance with some examples.

FIG. 4 is a system of a circuit that includes a Miller capacitor in testing circuitry for determining leakage current in various DUTs of different types in accordance with some examples.

FIG. 5 is a system of a circuit that includes a bias current with testing circuitry for determining leakage current in various DUTs of different types in accordance with some examples.

FIG. 6 is a system of a circuit that includes testing circuitry and a current-based sink path for determining leakage current in various DUTs of different types in accordance with some examples.

FIG. 7 is a system of a circuit that includes testing circuitry with a resistor-based sink path for determining leakage current in various DUTs of different types in accordance with some examples.

FIG. 8 is a system of a circuit that includes testing circuitry with a programmable array for determining leakage current in various DUTs of different type in accordance with some examples.

FIG. 9 is a system of a circuit that includes a calibration configuration of the amplifier in testing circuitry with a programmable array for determining leakage current in various DUTs of different type in accordance with some examples.

FIG. 10 is a system of a circuit that includes a calibration configuration of the current mirror in testing circuitry with a programmable array for determining leakage current in various DUTs of different type in accordance with some examples.

FIG. 11 is a process flow of a circuit that includes testing circuitry for determining leakage current in various DUTs of different types in accordance with some examples.

### DETAILED DESCRIPTION

Corresponding numerals and symbols in different figures generally refer to corresponding parts unless otherwise indicated. The figures are drawn to clearly illustrate relevant aspects of preferred embodiments and are not necessarily drawn to scale.

ICs are made through a fabrication process where layers are successively built on a semiconductor wafer through material depositions, photolithography, etches, chemical mechanical planarization (CMP), and other steps. The semiconductor wafer is typically a circular, disc-like structure that includes a number of die regions. The die are typically squares or rectangles that are arranged in a grid-like pattern over the face of the wafer. Each die includes a separate circuit. Thus, when fabrication of the various layers is complete, the disc-like wafer is cut into many die. Each die is then packaged to make a “chip”, such that a single wafer ultimately yields a large number of chips. Ideally, each die/chip would have the same electrical characteristics as one another. However, in reality, the die/chips have small variations in their electrical characteristics due to small, uncontrollable variations in the manufacturing process. Fabrication facilities strive to measure these variations as die/chips are made, and continually tune the fabrication process to help ensure the final die/chips have electrical characteristics that fall within acceptable ranges.

To measure the electrical characteristics over different die and different wafers, fabs often manufacture wafers that include commercial die and separate test die. The commercial die includes circuitry that will be packaged as chips to be sold, while the test die include test structures that allow the fab to characterize the electrical characteristics of devices, such as transistors, that are made in the fab. The test die are often discarded or kept for archival purposes after the electrical characteristics are measured, but generally are not sold.

One electrical characteristic that is important for ICs is leakage current. Leakage current is a major contributor to power consumption when ICs are in standby mode. In particular, the leakage current flowing through an individual transistor on a circuit can be small and nearly undetectable when the IC is powered off, and ideally would be zero. The leakage current changes as a function of voltage supply and temperature, so at low voltage supply and/or low temperatures, detecting leakage current for a transistor is even more difficult.

Some aspects of the present disclosure lie in the appreciation that there are advantages to including testing circuitry to measure leakage current for transistors on commercial die. In particular, in some examples provided in this disclosure, a single die includes commercial component circuitry and also includes test transistors or other devices under test (DUTs). The die also includes testing circuitry to measure and characterize leakage current for the transistors and/or other DUTs. Thus, the die can change between a “normal mode” in which the commercial component circuitry is used, and a “test mode” during which the leakage current for the transistors and/or other DUTs is measured. The test mode can be used both before and after deployment into the field, and the circuits are configured to minimize use of the silicon die area.

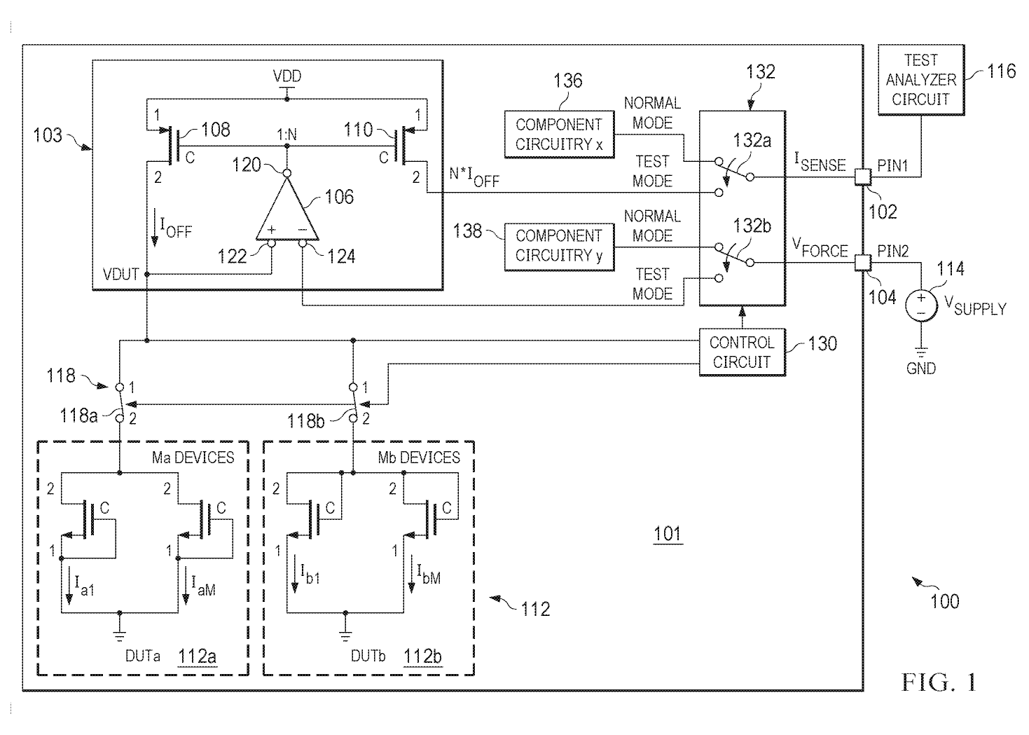

FIG. 1 illustrates an example system 100 including a circuit 101 that can change between a “normal mode” in which commercial component circuitry is used, and a “test mode” during which the leakage current for DUTs is measured. In an example, the circuit 101 can be an IC, a semiconductor die or chip that includes a silicon die area with various component circuitries 136, 138. The component circuitries 136, 138 can be structured to provide functionality. In some examples, the component circuitries 136, 138 can be a microprocessor; a baseband processing circuit; a direct current (DC)-to-DC converter; a transmission circuit, such as a radio frequency (RF) modulator; a reception circuit, such as an RF demodulator; and/or a radar circuit, among others. A first pin (Pin1) 102 and a second pin (Pin2) 104 act as points of contact between the component circuitries 136, 138 and external circuitry. The pins 102, 104 can be input pins, output pins, and/or bidirectional input/output (I/O) pins. The pins can be configured to be coupled to external circuitry, such as a printed circuit board, a component for power connection, a ground connection, data transmission, control/synchronization for specialized functions associated with the circuit 101, or other circuit functions.

In addition to the component circuitries 136, 138, and pins 102, 104, the circuit 101 further includes testing circuitry 103, DUTs 112a through 112b (collectively, or individually referred to as 112), DUT switches 118a through 118b (collectively, or individually referred to as 118), mode switches 132a through 132b (collectively, or individually referred to as 132), and a control circuit 130. The DUTs 112 are arranged into different sets or subsets of DUTs from among a total number of DUTs, with each subset having a different type of DUT or different characteristic than other sets or subsets of DUTs on the circuit or chip. The testing circuitry 103, DUT switches 118, mode switches 132, and control circuit 130 are configurable to work in conjunction with a test analyzer circuit 116 and voltage supply 114 to apply various bias conditions to the DUTs 112 to determine current leakage for each different type of DUT. During normal operation, the DUTs can be coupled to the component circuitry when testing is not being performed on them. The test analyzer circuit 116 and voltage supply 114 may be off-chip (e.g., coupled to circuits within the circuit 101 via pins 102, 104), but in other examples the test analyzer circuit 116 and/or voltage supply 114 can be included in circuit 101 (e.g., on the same substrate and/or within the same package as the other elements of circuit 101). The control circuit 130 can be a processor or logic circuit or alternatively can be a pin that is controlled by the test analyzer circuit 116 or another external circuitry (not pictured). In still other examples, the control circuit 130 can be a fuse, register, or other memory element that can be set or blown (e.g., after current leakage testing has been completed).

The control circuit 130 changes the states of mode switches 132a, 132b based on whether the circuit is in a “normal mode” of operation, or a “test mode” of operation. In the normal mode of operation, the control circuit 130 sets the states of the mode switches 132a, 132b to couple the component circuitries 136, 138 to the first and second pins 102, 104, respectively. Thus, in the normal mode of operation, the circuit uses component circuitries 136, 138 to achieve functionality and provides voltages and/or currents to the first pin 102 and/or second pin 104, and/or receives voltages and/or currents from the first pin 102 and/or second pin 104 to achieve functionality.

During the test mode of operation, the control circuit 130 changes the state of the mode switches 132a, 132b and couples the first pin 102 (and hence test analyzer circuit 116) to an output of the testing circuitry 103 and couples the second pin 104 (and hence voltage supply 114) to an input of the testing circuitry 103. While voltage supply 114 and test analyzer circuit 116 are coupled to the test circuitry 103, the control circuit 130 also closes one or more of the DUT switches 118 to measure leakage currents of the DUTs 112. For example, during a first time, the control circuit 130 can close a first DUT switch 118a while leaving a second DUT switch 118b open. Then, during this first time, the test analyzer circuit 116 and testing circuitry 103 can apply various bias conditions to measure current leakage for a first subset of DUTs 112a. During a second time of the testing mode, the control circuit 130 can open the first DUT switch 118a while closing the second DUT switch 118b. Then, during this second time, the test analyzer circuit 116 and testing circuitry 103 can apply various bias conditions to measure current leakage for a second subset of DUTs 112b.

To achieve testing functionality in an efficient manner, the testing circuitry 103 can include analog components such as an amplifier 106 and at least a pair of transistors (108, 110). Thus, the illustrated amplifier 106 includes a first input 122, a second input 124 and an output 120. The first transistor 108 and a second transistor 110 each include a first current terminal (first terminal) (1), a second current terminal (second terminal) (2), and a control terminal (C). The testing circuitry 103 is coupled to the sets of DUTs 112a, 112b via the one or more DUT switches 118a, 118b, respectively. Each DUT switch 118 includes a first terminal (1) and a second terminal (2) and is controlled via control circuit 130.

Advantageously, each DUT 112a or 112b can include an integer number of identical or nearly identical transistors or other devices, where the integer can be any integer greater than zero, and one or more DUTs 112a or 112b, or a subset (a portion of one or more) of DUTs of DUT 112a or 112b can be tested at a time in test mode. Often, the integer is 100 or more, because current leakage for individual transistors is very small so providing more transistors along current paths that are in parallel within a subset of DUTs can help to measure leakage current for an individual transistor type or a particular type of DUTs 112a or 112b. In the illustrated example, two different types of DUTs (e.g., DUT 112a, 112b) are illustrated, though any number of different types of DUTs can be included. More particularly, a first set of DUTs 112a can include Ma transistors that each share a first set of transistor characteristics; and a second set of DUTs 112b can include Mb transistors that each share a second set of transistor characteristics. For instance, in some examples, the first subset of DUTs 112a can include Ma = 100 or more transistors, and each of these Ma transistors of DUT 112a can be an n-channel MOSFET (nMOSFET) that is identical to the other transistors of the Ma transistors, notwithstanding differences due to tolerances in the manufacturing process. Similarly, the second set of DUTs 112b can include Mb = 100, less or more transistors (where Mb can be equal to or different than Ma), and each of these Mb transistors of DUT 112b can be a p-channel MOSFET (pMOSFET) that is identical to the other transistors of the Mb transistors, notwithstanding differences due to tolerances in the manufacturing process. In other examples, each of the Ma transistors can be an n-channel MOSFET (nMOSFET) with a first width-to-length ratio (e.g., w/l = 1:1); and each of these Mb transistors can be an n-channel MOSFET (nMOSFET) with a second width-to-length ratio (e.g., w/l = 5:1). In still other examples, each transistor in the first subset of DUTs can be a first type of transistor, such as a planar MOSFET, and each transistor in the second set of DUTs 112b can be a second type of transistor, such as a finFET or bipolar junction transistor (BJT). Thus, in each example above, the first set of DUTs 112a are first transistors that are designed to have the same transistor characteristics as one another, and the second set of DUTs 112b are second transistors that are also designed to have the same characteristics as one another, albeit different from the characteristics of the first transistors.

The first input 122 of the amplifier 106 is coupled to the first terminals of the DUT switches 118a, 118b and to the second terminal of the first transistor 108. The second input 124 of the amplifier 106 is coupled to the second mode switch 132b. The output 120 of the amplifier 106 is coupled to the control terminals of the first transistor 108 and the second transistor 110, where each of the control terminals of first and second transistors 108 and 110 are coupled to one another. The first terminal of the first transistor 108 is coupled to the first terminal of the second transistor 110, and both are coupled to VDD.

When closed, a DUT switch (e.g., 118a or 118b) couples the first input 122 of the amplifier 106 to the second terminals of the selected set of DUTs (e.g., 112a or 112b, respectively). Within the first subset of DUTs 112a, the control terminal of the Ma devices are coupled to ground (GND), such that the transistors in subset 112a have a gate-source voltage (VGS) that is generally zero (and/or less than the voltage threshold of the transistors in subset 112a), and the transistors in subset 112a are “off”. Within the second subset of DUTs 112b, the control terminal of the Mb devices are coupled to the second terminal of switch 118, such that the transistors in the set of DUTs 112b have a source-gate voltage (VSG) that is generally zero (and/or less than the magnitude of the voltage threshold of the transistors in set of DUTs 112b, and the transistors in set of DUTs 112b are also “off”. Therefore, because transistors in DUTs 112a and 112b are “off”, they are primed for a current leakage measurement when the testing circuitry 103 applies a drain-to-source (VDS) voltage to the transistors in DUTs 112a, 112b.

When the circuit 101 is in the test mode, the leakage current for a selected DUT subset (e.g., Ioff at VDUT) is measured by the test analyzer circuit 116, which operates via probes or other contacts coupled to the pins 102, 104 of the circuit 101. The voltage supply 114 coupled to the second pin 104 provides a force voltage (V_{Force}) to the testing circuitry 103 on the circuit 101, while the test analyzer circuit 116 coupled to the first pin 102 detects or senses a sense current (Isense) to measure and determine the leakage current at the selected DUT subset. The voltage V_{Force} is used to stimulate a response by the selected DUT subset in order for the test analyzer circuit 116 to observe a response in terms of current, voltage or other parameters, enabling the verification of the DUT's functionality, performance, and adherence to specifications. If no additional currents are present, the current on the sense current Isense at the first pin 102 is the amount of leakage current multiplied by current gain N.

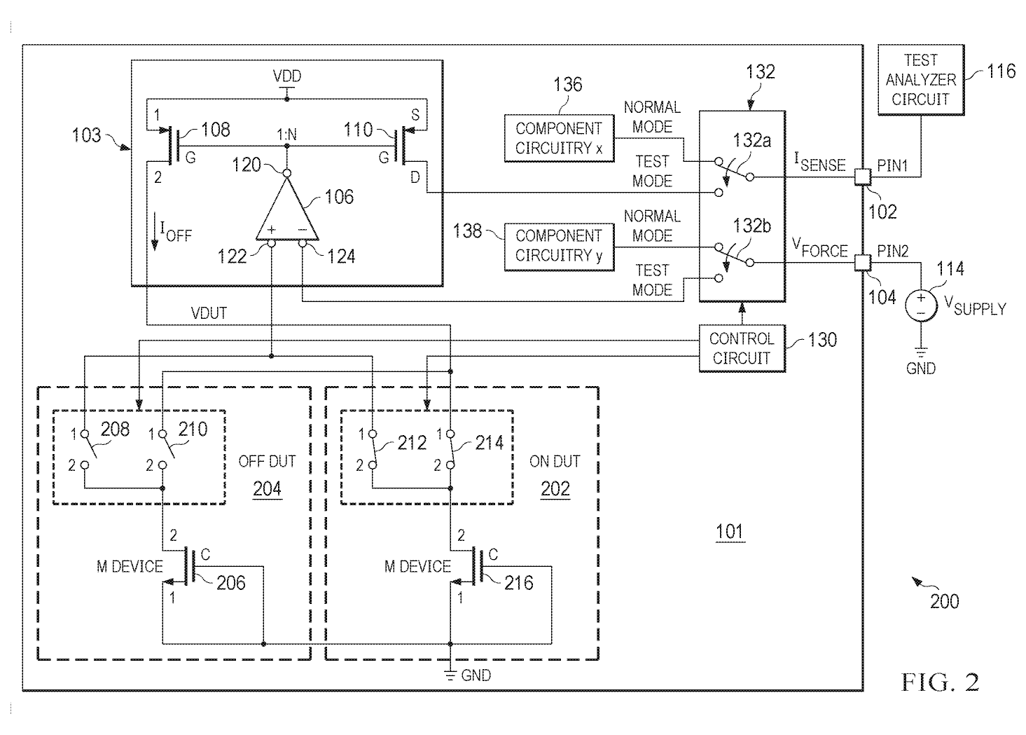

In the test mode of operation, the amplifier 106 receives V_{Force} on its first input 124 and drives the transistors 108 and 110 with a 1:N current gain ratio, thereby provides a DUT voltage VDUT at the second terminals 2 of the selected DUT. VDUT generally tracks VForce, and N is an integer greater than one (e.g., 10, 100, 1,000 or other N integer). The first transistor 108, at a left mirror branch of the testing circuitry 103, drives a current Ioff onto the selected DUT. This current Ioff induces a corresponding leakage current in the selected DUT (e.g., 112a) and the voltage VDUT settles to the force voltage V_{Force}, which can be further configured in closed-loop operation with the testing circuitry 103 as further described in FIG. 2. The leakage current for the selected set of DUTs (e.g., 112a or 112b) can then be measured on the first pin 102, for example, as Isense divided by a calibrated gain N of the transistors 108 and 110. The current leakage of an individual transistor within the selected sets of DUTs (e.g., within DUT 112a) can then be determined by dividing this leakage current by the number of transistors in the subset (e.g., dividing by Ma when leakage current for DUT 112a is measured).

Testing circuitry 103 operates to increase current Ioff at the second terminal of DUT 112 to a measurable value for measurement by the test analyzer circuit 116, while the DUT 112 is powered off or idle. Because leakage current is a function of the voltage supply 114, the more that the voltage supply 114 is increased, the more leakage current that occurs at the drain terminal of the DUT 112. In order to accurately characterize the leakage current of the DUT 112, testing in test mode can be performed under a range of voltages and temperatures in order to target measurable leakage currents at particular target values and assess electrical behavior of the DUT 112.

After measuring and characterizing the leakage current in the set of DUTs 112 by the test analyzer circuit 116, the control circuit 130 can signal the DUT switches 118 and mode switches 132 to return to a normal mode of operation for field use, such as in a computer or other device specific for operation by the circuit.

Advantageously, the circuit 101 can include a single substrate having component circuitries 136, 138 to provide functionality and having DUTs 112 that allow the measurement/characterization of leakage currents for a variety of different DUTs. The presence of multiple identical or nearly identical transistors arranged on parallel current paths for the DUT subset allows greater leakage currents to be measured than approaches with only one transistor for each DUT type. Further, because the testing circuitry 103 can have a large current gain, it limits the number of DUTs needed for measurement of very low leakage currents and therefore promotes a small footprint that doesn’t consume an unduly large area on the die. Therefore, the circuit 101 of FIG. 1 strikes a good balance that allows manufacturers to include DUTs on commercial wafers to measure/characterize leakage currents, and reduces fab “waste” attributable to discarded test chips. Also, because every die on a wafer (not merely test die) can include DUTs, this approach can also allow for more uniform characterization of leakage current over entire wafers compared to some other approaches.

FIG. 2 illustrates another example system 200 with testing circuitry as analog testing equipment on the circuit 101 for measuring leakage current of DUTs in a test mode. The circuit 101 includes the DUT 202 and DUT 204. DUT 204 includes at least one device or transistor 206 to be tested, a first switch 208, and a second switch 210; and DUT 202 comprises at least one transistor 216, a third switch 212 and a fourth switch 214. DUT 204 includes one or more transistors 206 or semiconductor devices comprising a characteristic or parameter that is different from the device(s) or transistor(s) 216 of DUT 202. Each DUT 202 or 204 can include a particular type of transistor device (e.g., n-channel MOS (NMOS) transistors, p-channel metal oxide semiconductor (PMOS) transistors, a same size transistor, or be of a particular transistor characteristic or type). For example, DUT 202 can include M transistors 216 (also can be referred to as transistor(s) 112 or transistor devices) of FIG. 1 and can be a different type or characteristic from the transistor(s) 206 of DUT 204 on the circuit 101. For example, the transistor(s) 206 of DUT 204 can be a first size, type or characteristic that is different from that of the transistor(s) 216 of DUT 202.

DUT 202 and 204 include M devices or transistors 216, 206 of a different type from one another, each transistor including a first terminal (1), a second terminal (2) and a control terminal (C), respectively. Control terminals of transistors 216, 206 of the DUT 202 and 204 are coupled to the first terminals of these same transistors 216, 206, which are also coupled together between the DUT 202 and 204. The first switch 208 of DUT 204 includes a first terminal (1) and a second terminal (2), with the first terminal of the first switch 208 coupled to the first input 122 of the amplifier 106. The second terminal of the first switch 208 is coupled to the second terminal of transistor 206 of the DUT 204. The second switch 210 of DUT 204 likewise includes a first terminal and a second terminal, with the first terminal of the second switch coupled to the second terminal of transistor 108 and the second terminal of the second switch 210 coupled to the second terminal of the transistor(s) 206 of DUT 204.

The DUT 202 includes transistor(s) 216 (also referred to as transistor(s) 112) in FIG. 1, and at least one or more third and fourth switches 212 and 214, each including first and second terminals. The first terminal of the third switch 212 is coupled to the first input 122 of the amplifier 106 and to the first terminal of first switch 208. The second terminal of the third switch 212 is coupled to the second terminal of the transistor(s) 216 of the DUT 202. The first terminal of the fourth switch 214 is coupled to the second terminal of the first transistor 108 and to the first terminal of the second switch 210. The second terminal of the fourth switch 214 is coupled to the second terminal of the transistor(s) 216 of DUT 202.

The testing circuitry 103 is configured with the DUTs in a closed loop configuration, operable to test the M devices of each DUT 202, 204 independent from one another in test mode. The control circuit 130 signals one or more sets of devices of DUTs to be closed off via switches 208 thru 214, while one set of devices of a DUT is activated and coupled into a closed loop with the testing circuitry 103. For example, DUT 202 can be signaled on or activated with switches 212, 214, while DUT 204 is signaled off or deactivated at switches 208 and 210. In this example, leakage current of DUT 202 can be effectively measured in the test mode configuration with the testing circuitry 103. The first and second transistors 108 and 110 are coupled to the amplifier 106 that operates to provide a target voltage on the DUT being tested for measuring the leakage current in the closed loop configuration. For example, a target voltage, Vsense, can be about 1 volt or .75 volt at the drain terminal or second terminal of the transistors of DUT 202. The leakage current on the device(s) or transistor(s) 216, for example, can be mirrored and measured at the first pin 102 as Isense at a measurable value generated by the closed loop configuration formed by the transistors 108 and 110, the amplifier 106, and the DUT 202, while DUT 206 is decoupled or isolated from being tested.

The current gain N as a gain factor enables the DUT 202 to be tested with fewer M DUTs or M devices in a reduced overall area, while making the DC sensitivity of the drain of the DUT 202 faster at reaching the target voltage by operating in such a closed-loop configuration. N can be any integer greater than one (e.g., less than, equal to or greater than 256), and M can be a different integer (one or greater than one) for the DUT 202 and DUT 206 (e.g., DUT 202 can have 10 transistor device with M = 10, while at DUT 206 M is equal to 100).

Because Ioff, as the leakage current, is no longer driving any external capacitance in closed-loop, the speed of the drain of the DUT 202 is increased, settling faster to the target voltage for measuring leakage current than without the amplifier 106. In other words, the external capacitances that could otherwise be introduced from the test analyzer circuit 116, parasitic capacitances on the chip or silicon die of the circuit 101, chip package, printed circuit board (PCB) or the like, are thus removed, enabling the target voltage to settle faster at the drain terminal of the DUT 202, and enabling faster measuring of the leakage current at targeted DUTs by the test analyzer circuit 116. A voltage sweep can be sped up in a closed-loop configuration as illustrated, reducing transient time before the drain or second terminal of the DUT that is activated settles to a target. In this manner, the leakage current of a particular set of devices (e.g., transistors 216 of DUT 202) with a first characteristic can be determined before isolating another set of devices of another DUT (e.g., transistors 206 of DUT 204) having another characteristic into the closed-loop configuration. The leakage current can then be measured on the first pin 102, for example, as Isense divided by a calibrated gain N of the transistors 108 and 110.

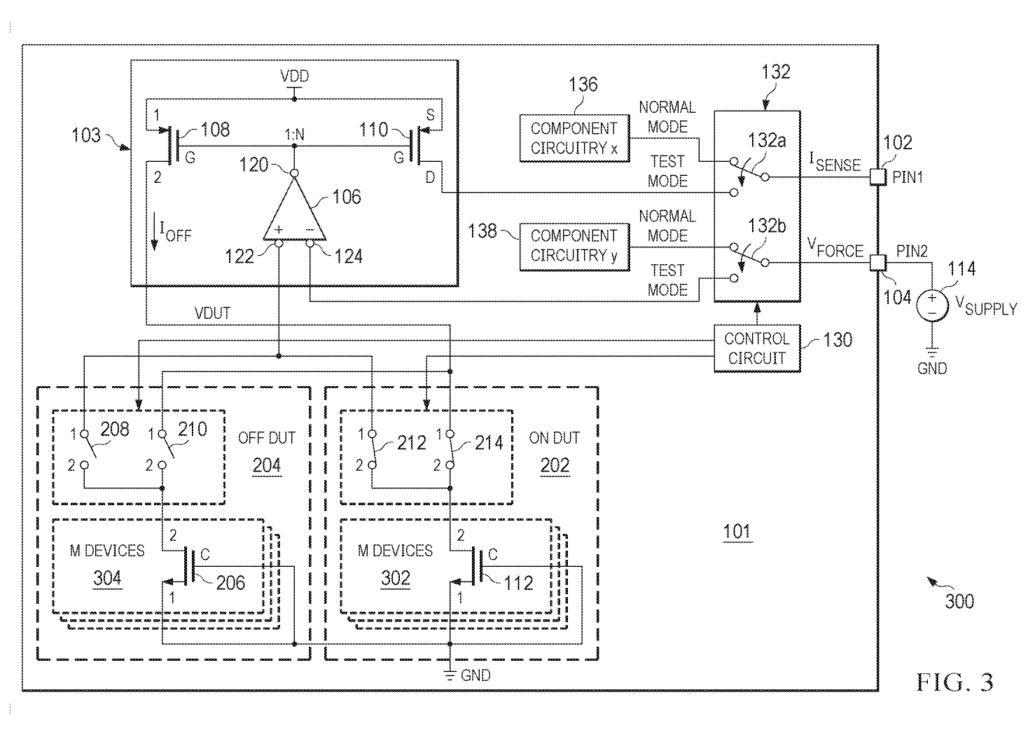

FIG. 3 illustrates another example system 300 with testing circuitry as analog testing equipment on the circuit 101 for measuring leakage current at each of the DUTs in a test mode. The circuit 101 includes the DUT 202 and DUT 204. DUT 204 comprises a first set 304 (one or more) of M devices or transistors, a first switch 208, and a second switch 210, and DUT 202 comprises a second set 302 of M devices or transistors, the third switch 212 and the fourth switch 214. DUT 204 includes one or more transistors 206 or semiconductor devices comprising a characteristic or parameter different from the transistors 216 of DUT 202, and vice versa. For example, the devices of one DUT can be NMOS transistors, PMOS transistors, the same size transistor as one another compared to other DUTs, MOSFET devices, bipolar junction transistor (BJT) devices, drain-extended NMOS / PMOS devices, or other particular transistor characteristic or type, different from that of other DUTs. For example, DUT 204 can include transistors 206 with a different threshold voltage than those transistors 216 of DUT 202 and measuring the leakage current of the different DUTs separately can determine a local variation among the devices to measure matching between the two. Alternatively, or additionally, an average voltage threshold can be measured with a sufficient number of M devices at each set 302 and 304 so local mismatches are averaged out or more negligible.

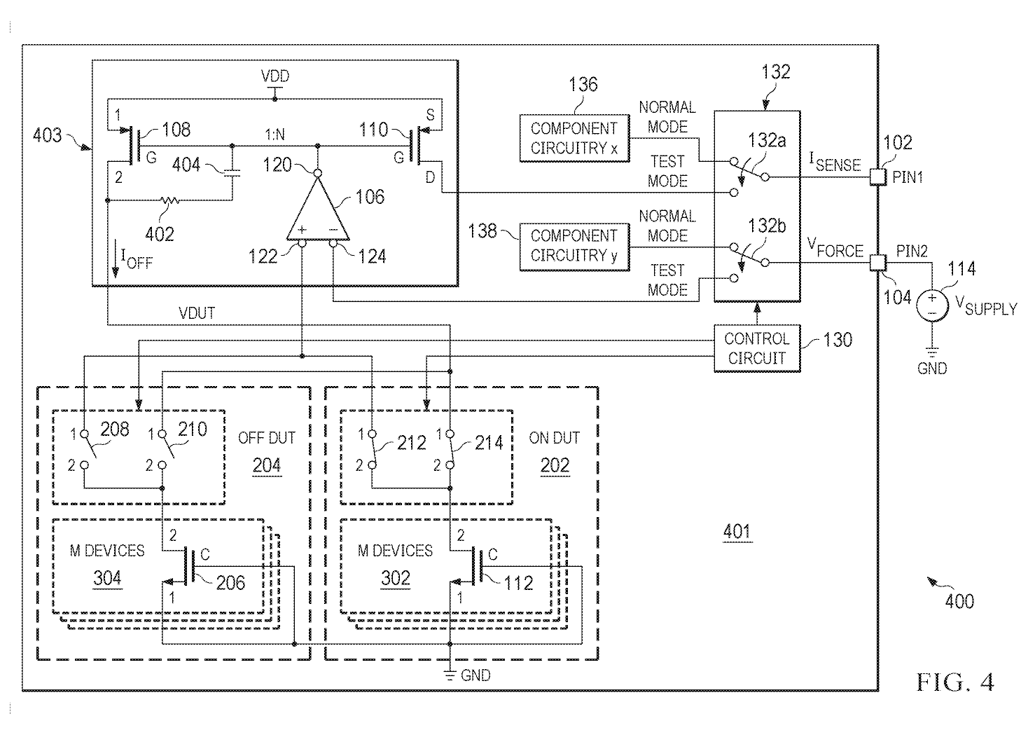

FIG. 4 illustrates another example system 400 with testing circuitry as analog testing equipment on the circuit 401 for measuring leakage current at each of the DUTs in a test mode. The testing circuitry 403 of the circuit 401 further includes a Miller capacitor 404 and a resistor 402 coupled together. The Miller capacitor 404 is coupled to the control terminal of the first transistor 108 and to the output 120 of the amplifier at a first terminal and to the resistor at a second terminal. The resistor is coupled to the drain or second terminal of the first transistor. The voltage gain at the control terminals of the first and second transistors 108, 110 leads to a higher effective input capacitance at Miller capacitor 404, giving a Miller capacitance, as a Miller capacitor 404.

The Miller capacitor 404 operates to make the output of the amplifier 106 a more dominant pole in the system 300's transfer function caused by the dynamic behavior of the testing circuitry 403 in closed loop configuration. Poles associated with the output of the amplifier 106 and the drain or second terminal of the DUT activated in the closed loop configuration are further separated in frequency than without the Miller capacitor 404, leading to a more stable system in the test mode of operation.

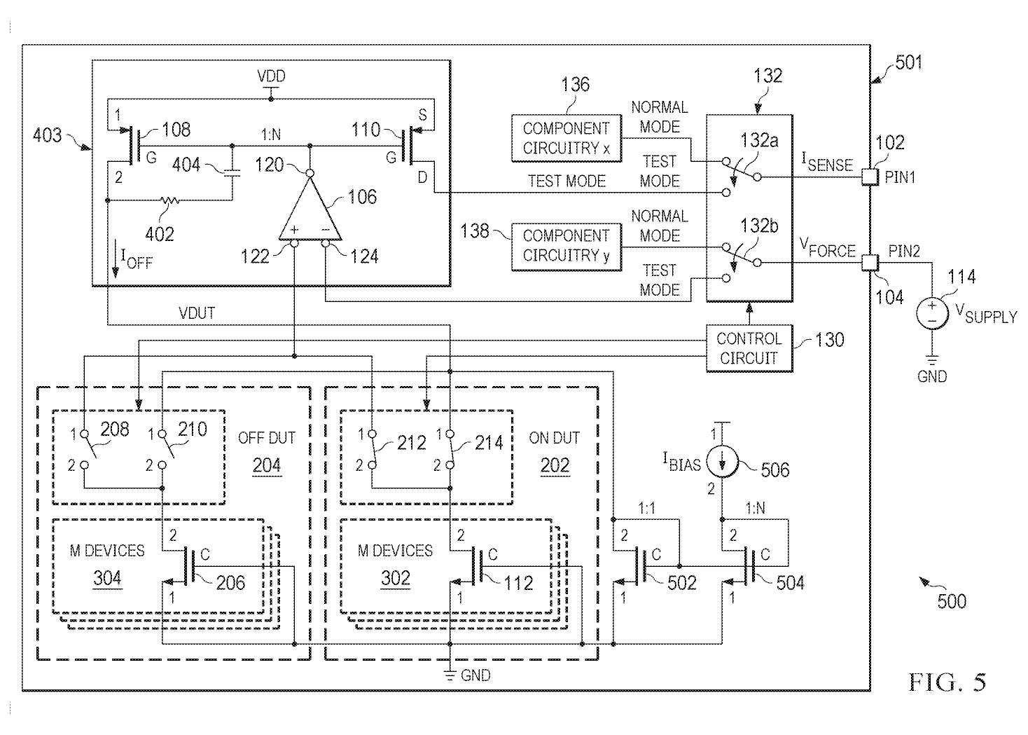

FIG. 5 illustrates another example system 500 with testing circuitry as analog testing equipment on the circuit 501 for measuring leakage current at each of the DUTs in a test mode. The system 500 includes a transistor 502, a transistor 504, and a current source 506.

Transistors 502 and 504 include a first terminal, a second terminal and a control terminal. The second terminal (e.g., a drain terminal) of transistor 502 is coupled to the second terminal of the first transistor 108. The first terminal of the transistor 502 is coupled to the first terminal of devices of the DUTs 202 and 204. The control terminal of the transistor 502 is coupled to the second terminal of transistor 502. The second terminal of the transistor 504 is coupled to the control terminal of the transistor 504 and to the current source 506. The first terminal of the transistor 504 is coupled to the first terminal of the transistor 502. The control terminal of the transistor 504 is coupled to the control terminal of the transistor 502. The transistors 502 and 504 are illustrated in this example as NMOS transistors, in which the first terminals can be source terminals, the second terminals can be drain terminals, and the control terminals can be gate terminals for example, although other devices can also be utilized in lieu of such as BJTs or PMOS transistors, for example.

The current source 506 coupled to transistors 504 and 502 further increases or improves matching between the transistors 108 and 110 even at low leakage current levels by ensuring a certain operation point of a minimum gate-source voltage minus a threshold voltage, referred to as a V_{GST} voltage operating point for the transistors 108 and 110 in current mirror configuration. Without the operating point threshold, the V_{GST} voltage of transistors 108 and 110 can be very small with low leakage currents, resulting in a poor current matching between these transistors, and a disadvantage when leakage currents become smaller, especially at lower temperatures.

The current source 506 provides a bias current (Ibias) to the closed loop configuration in test mode by providing the bias current to the drain terminal or second terminal of transistor 108, operating to further make the output 120 of amplifier 106 a more dominant pole in the system's transfer function of dynamic behavior. The bias current Ibias (e.g., one micro-amp or other value) ensures that the second terminal of the DUT activated into the closed loop is at a higher frequency than at the output of the amplifier 106, regardless of the leakage current. The bias current could be greater than the leakage current to be measured, so the system 500 can calibrate Isense at the pin 102 first with all DUTs disabled/deactivated to first measure Isense due to the bias current Ibias as a reference before then measuring or characterizing the leakage current of DUT 202 or 204, for example.

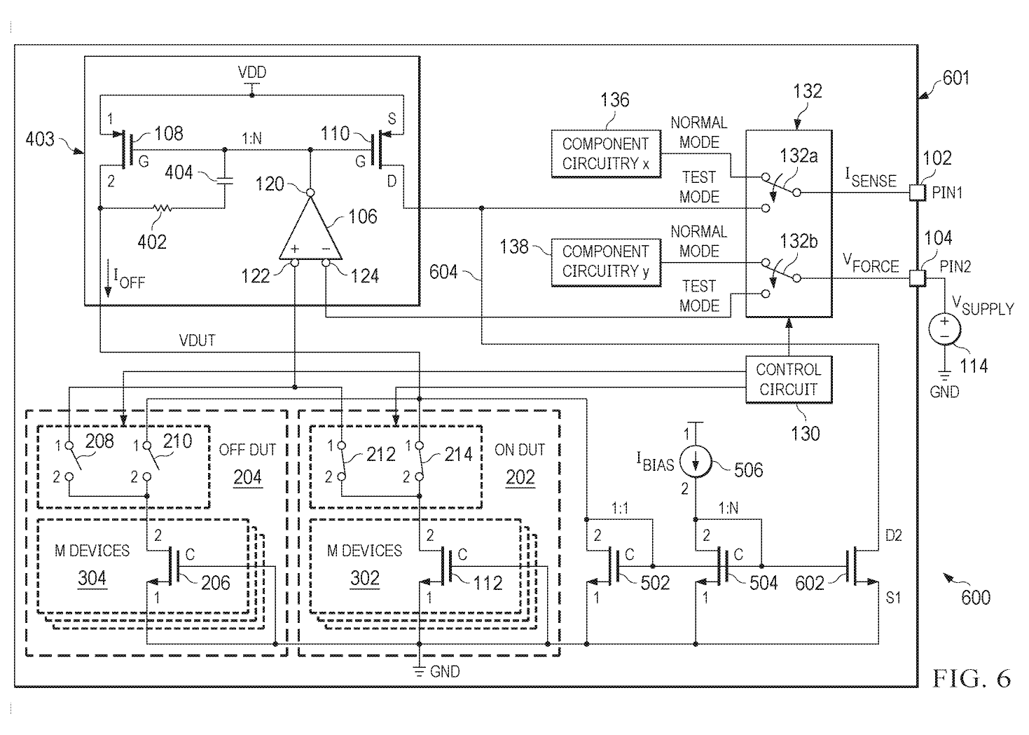

FIG. 6 illustrates another example system 600 with testing circuitry as analog testing equipment on the circuit 601 for measuring leakage current at each of the DUTs in a test mode. The system 600 includes a transistor 602 and a branch 604 as a current-based sink path.

The transistor 602 includes a first terminal, a second terminal and a control terminal. The second terminal of the transistor 602 is coupled to the second terminal of the second transistor 110 via the branch 604. The control terminal of the transistor 602 is coupled to the control terminal of the transistor 504, and the first terminal of the transistor 602 is coupled to the first terminal of the transistor 504.

The branch 604 sinks the bias current scaled by the current gain N from the first and second transistors 108 and 110 into the transistor 602, thereby removing the bias current from the sensing output to be measured at the first pin 102 by the test analyzer circuit 116. The test analyzer circuit 116 therefore receives N times the leakage current at the DUT activated in the closed loop configuration. Thus, the transistor 602 coupled to the current source 506 through the transistor 504 operates by sinking a replica of the current bias Ibias generated by the transistors 108 and 110, leaving the leakage current times the current gain at the first pin 102. The branch 604 coupled to the transistor 602, which in turn is coupled to the current source 506 via the transistor 504 improves the accuracy of the test for leakage current, relying less on the accuracy or level of resolution of the test analyzer circuit 116.

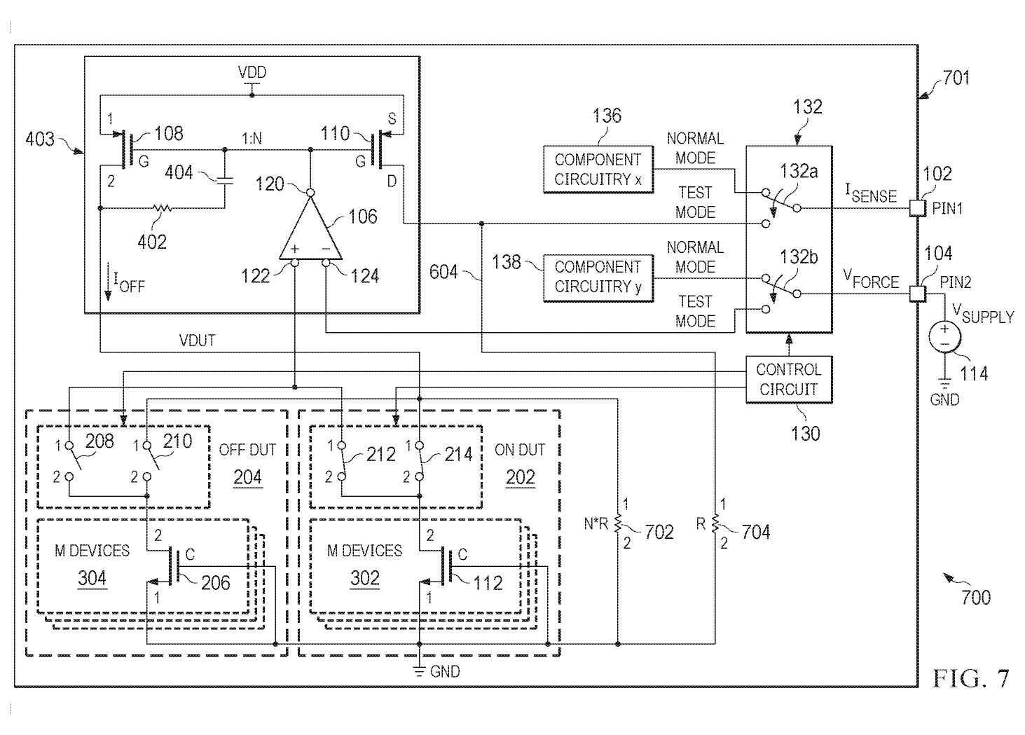

FIG. 7 illustrates another example system 700 with testing circuitry as analog testing equipment on the circuit 701 for measuring leakage current at each of the DUTs in a test mode. The system 700 includes a first resistor 702 having a first impedance and a second resistor 704 having a second impedance that is a different impedance than the first impedance.

First and second resistors 702 and 704 include first and second terminals, respectively. The first terminal of the first resistor 702 is coupled to the second terminal of the first transistor 108. The second terminal of the first resistor 702 is coupled to the first terminals and the control terminals of the transistors of the DUTs 202 and 204. The first terminal of the second resistor 704 is coupled to the drain of the second transistor 110 via the branch 604 as a resistor-based sink path. The second terminal of the second resistor 704 is coupled to the second terminal of the first resistor 702.

The impedance of resistor 702 can be scaled based on the current gain N of the transistors 108 and 110. Resistors 702 and 704 are configured to create a current formed by the voltage supply V_{Force} from the voltage supply 114 divided by the current gain times the impedance, represented as: V_{Force} / (N*R). The V_{Force} is the voltage at the drain or second terminal of the DUT 202, 204 (V_{DUT}) so that V_{DUT} / (N*R) determines Ibias. Because the impedance of resistors 702 and 704 can be lower than the output impedance of a current source (e.g., current source 506 of FIGS. 5 or 6), the frequency of the pole at the drain terminal or second terminal of the DUT 202 or 204 can be higher with an increased phase margin. Poles of the system's transfer function associated with the output of the amplifier 106 and the drain or second terminal of the activated DUT in the closed-loop configuration can be further separated, providing for a greater stability and more accurate testing of the DUTs in test mode. With resistors 702 and 704, leakage current stabilizes faster within the closed loop configuration in the test mode of operation.

In an example, in the test mode the amplifier 106 provides a force voltage V_{Force}, as a target voltage V_{DS}, on the second terminal of the DUT 202 or 204. The force voltage V_{Force}, for example, can be .75 to 1 volt. Then the bias current from voltage on the DUT is provided through the resistor 702 (N*R), as .75 to 1 volt over the resistor value of resistor 702. With the resistor 704 (having a resistance R) and resistor 702 being of a ratio or proportion to one another by N, the bias current can be replicated in a current that is N times larger so that the bias current that is injected into the current mirror formed by transistors 108 and 110 can be canceled for a more accurate leakage measurement at the first pin 102.

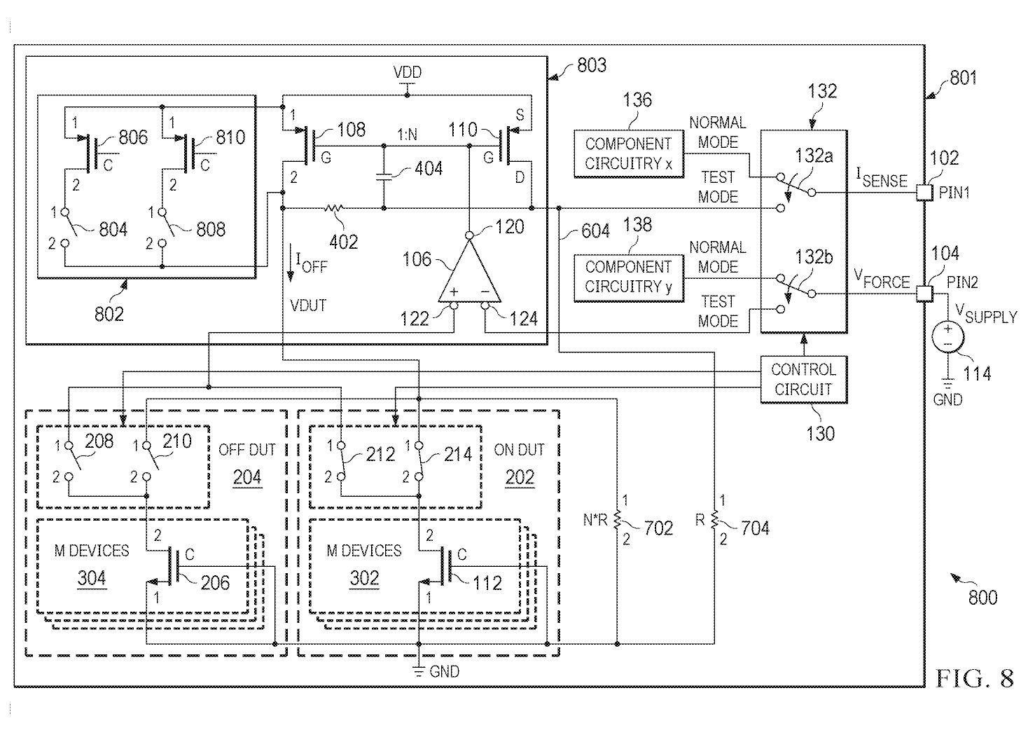

FIG. 8 illustrates another example system 800 with testing circuitry as analog testing equipment on the circuit 101 for measuring leakage current at each of the DUTs in a test mode. The system 800 includes a programmable array 802 coupled to the first transistor 108 in testing circuitry 803.

The programmable array 802 includes a first set of switches 804, a first set of transistors 806, a second set of switches 808, and a second set of transistors 810. The first and second set of switches 804 and 808 each include a first terminal and a second terminal, respectively. The first and second set of transistors 806 and 810 each include a first terminal, a second terminal and a control terminal. The first terminals of the first and second set of switches 804 and 808 are coupled to the second terminals of the first and second set of transistors 806 and 810, respectively. The second terminals of the first and second set of switches 804 and 808 are coupled to the second terminal of the first transistor 108. The first terminals of the first and second set of transistors 806 and 810 are coupled to the first terminal of the first transistor 108.

The programmable array 802 can be configured based on the DUT 202, 204 that is being activated into the closed loop configuration via switches, making the configuration of the transistors 108 and 110 dynamic in operation. The first and second set of transistors 806 and 810, for example, can be coupled in parallel to the first transistor 108. Depending on the value of N as the desired current gain between the transistors 108 and 110, the number of transistors of the programmable array 802 can be activated or deactivated via the switches 804 and 808, respectively. If a larger gain is desired from the left side branch with transistor 108 to the right-side branch with transistor 110, then fewer transistors could be connected via switches in the programmable array 802. However, to reduce N, the programmable array 802 is connected on the left side in parallel to transistor 108. In this manner, the current gain can be appropriately selected for targeting certain current ranges going into the test analyzer circuit 116 (e.g., 1 micro-ampere or milli-ampere).

Although the programmable array 802 is connected to transistor 108 on the left side branch, alternatively, or additionally, another similar programmable array could be connected across transistor 110 in a similar configuration. In this configuration, the current gain N can be increased on the right side at transistor 110 by activating or connecting additional transistors in parallel, while disconnecting transistors in the programmable array 802, for example. In particular, on the side of the DUTs at transistor 108 the stability of the closed-loop configuration could vary among different transistor types of different DUTs, depending on the DUT 202, 204 being activated for testing, as well as vary among different temperatures. Leakage current changes exponentially with temperature, so adding the programmability on the left side to the matching of transistors 108 and 110 can enable the current density of the circuit to be maintained in a tighter range, also leading to a tighter gate to source voltage V_{GS} and achieve better matching.

Although the programmable array 802 of system 800 coupled to transistor 108 is illustrated with resistors 702 and 704 of system 700 of FIG. 7, the programmable array 802 can also be coupled to transistor 108 in any one of the other configurations described in this disclosure. For example, resistors 702, 704 can alternatively be replaced by the configuration of transistors 502, 504, or 602, along with current source 506.

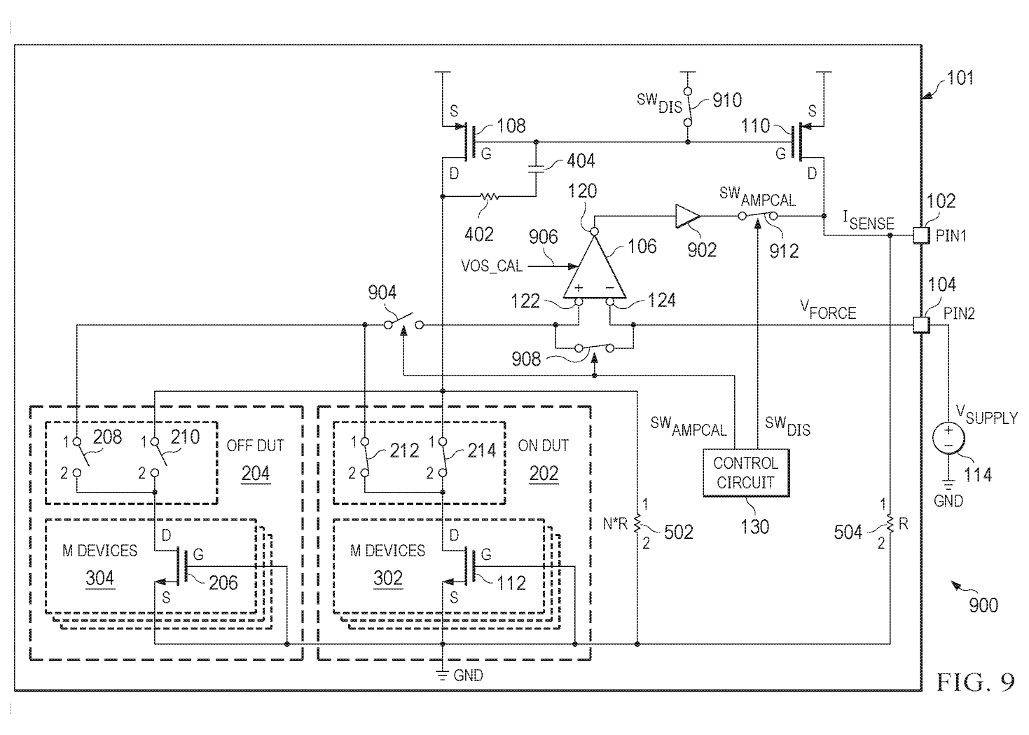

FIG. 9 illustrates an example system 900 for calibration of the amplifier 106. In this example, the system 900 comprises a Schmitt trigger 902, and switches 904 thru 912. The amplifier 106 has a calibration mode of operation that enables calibration with an input offset voltage as a differential calibration voltage (Vos_cal) 906. The output 120 of the amplifier 106 is disconnected from transistors 108 and 110 via switch 910 and coupled to a comparator 902. The comparator 902 can be a Schmitt trigger, for example, receiving an analog signal from the amplifier 106 and converting it to a square wave or digital output for calibration of the amplifier 106 via calibration voltage 906. The switch 912 couples the comparator 902 to the first pin 102, while the switch 904 disconnects DUTs 202 and 204 from calibration of the amplifier 106. Switch 908 couples the inputs 122 and 124 of the amplifier to the second pin 104 for receiving a voltage supply. The amplifier 106 is then placed in an open loop by disconnecting the closed loop operation with the DUTs and testing circuitry 103 or 403. The calibration signal to the amplifier 106 can be swept until the output of the comparator 902 flips, for example. The calibration offset can be less than 2 millivolts, for example. By modifying the offset of the amplifier 106, the amplifier 106 can be calibrated to reduce error that could result from forcing the force voltage V_{Force} on the second pin 104 to the DUTs 202, 204 when in test mode.

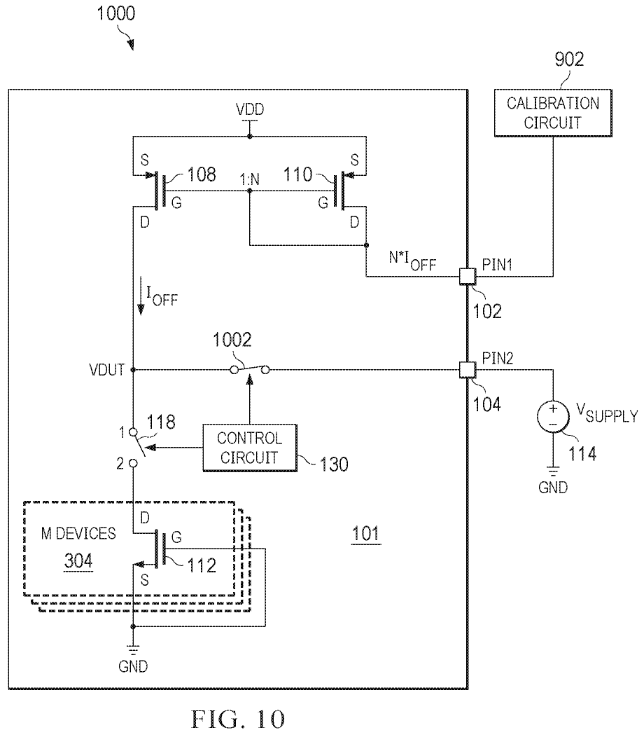

FIG. 10 illustrates an example system 1000 for calibration of the first and second transistors 108 and 110 with gate or control terminals coupled to one another. Here, the current mirror configuration can be coupled to switch 1002. Although components or testing circuitry illustrated in FIGS. 1 through 9 are not shown for simplicity of illustration, these components can still be incorporated as in other descriptions with illustration of the disclosure, which can be disabled for calibration of the transistors 108, 110, 806, 810, etc. thru switching components (not shown). The transistors 108 and 110 can be sized for a 5% mismatch for example, including switches to measure any mismatch and calibrate accordingly to further reduce any error on the current measurement on the second pin 104 in the process.

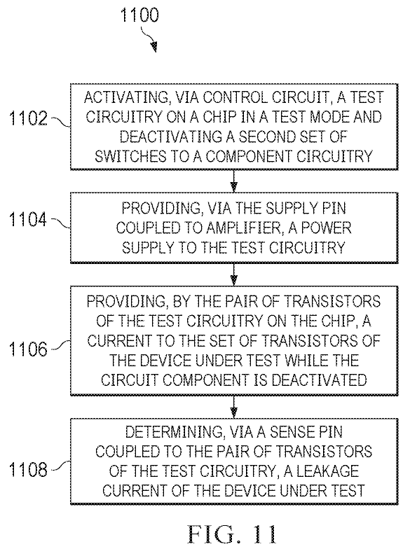

FIG. 11 illustrates an example process flow 1100 for testing DUTs 202 or 204 in a test mode. At 1102, the circuit (e.g., any one of circuit 101 to 801) activates, via control circuit 130, testing circuitry 103, 403 on a chip in a test mode by activating a first set of switches 208, 210, 212, or 214 coupled to a DUT (e.g., 202, 204) and deactivating a second set of mode switches 132 to component circuitry 136, 138. The device under test comprises a set of transistors coupled to a supply pin via the first set of switches, and the test circuitry comprises an amplifier and a pair of transistors. At 1104, the circuit (e.g., any one of circuit 101 to 801) provides, via the supply pin or second pin 104 coupled to the amplifier 106, a supply to the testing circuitry 103, 403 coupled to the DUT 202, 204. At 1106, the circuit provides, by the pair of transistors of the test circuitry on the chip, a current to the set of transistors of the device under test in a closed-loop configuration while the component circuitry 136, 138 is deactivated. At 1108, the circuit with test analyzer circuit 116 determines, via a sense pin or first pin 102 coupled to the pair of transistors of the test circuitry, a leakage current of the DUT 202, 204, responsive to a voltage supply at the second pin 104, for example.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. In other cases, the devices described herein are “configurable to” perform a task or function, meaning that the hardware present in the device is suitable to be programmed after manufacturing to perform the function via firmware and/or software programming of the device, and the firmware and/or software is not included at the time of manufacture.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor, a bipolar junction transistor (BJT – e.g. NPN or PNP), insulated gate bipolar transistors (IGBTs), and/or junction field effect transistors (JFETs) may be used in place of or in conjunction with the devices described herein. The transistors may be depletion mode devices, drain-extended devices, enhancement mode devices, natural transistors or another type of device structure transistor. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. Also, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/- 10 percent of that parameter. Modifications are possible in the described examples, and other implementations are possible, within the scope of the claims.

What is claimed is:

1. A circuit, comprising:
an amplifier including an output and an input;
a first transistor including a first current terminal, a second current terminal, and a control terminal, the control terminal of the first transistor coupled to the output of the amplifier;
a second transistor including a current terminal and a control terminal, the current terminal of the second transistor coupled to the first current terminal of the first transistor, the control terminal of the second transistor coupled to the control terminal of the first transistor and to the output of the amplifier; and
a third transistor including a first current terminal, a second current terminal and a control terminal, the second current terminal of the third transistor coupled to the input of the amplifier and to the second current terminal of the first transistor, and the control terminal of the third transistor coupled to the first current terminal of the third transistor.

2. The circuit of claim 1, further comprising:
a fourth transistor including a first current terminal, a second current terminal and a control terminal, the control terminal of the fourth transistor coupled to the control terminal of the third transistor and to the first current terminal of the third transistor;
a first switch including a first terminal and a second terminal, the first terminal of the first switch coupled to the input of the amplifier, the second terminal of the first switch coupled to the second current terminal of the fourth transistor; and
a second switch including a first terminal and a second terminal, the first terminal of the second switch coupled to the second current terminal of the first transistor, the second terminal of the second switch coupled to the second current terminal of the fourth transistor.

3. The circuit of claim 2, further comprising:
a third switch including a first terminal and a second terminal, the first terminal of the third switch coupled to the input of the amplifier and to the first terminal of the first switch, the second terminal of the third switch coupled to the second current terminal of the third transistor; and
a fourth switch including a first terminal and a second terminal, the first terminal of the fourth switch coupled to the second current terminal of the first transistor and to the first terminal of the second switch, the second terminal of the fourth switch coupled to the second current terminal of the third transistor.

4. The circuit of claim 2, further comprising:
a set of third transistors coupled to the third transistor, the third transistor and the set of third transistors comprising a first characteristic; and
a set of fourth transistors coupled to the fourth transistor, the fourth transistor and the set of fourth transistors comprising a second characteristic, wherein the first characteristic is different than the second characteristic.

5. The circuit of claim 1, further comprising:
a resistor including a first terminal and a second terminal, the first terminal of the resistor coupled to the second current terminal of the first transistor; and
a capacitor including a first terminal and a second terminal, the first terminal of the capacitor coupled to the control terminal of the first transistor and the second terminal of the capacitor coupled to the second terminal of the resistor.

6. The circuit of claim 1, further comprising:
a fifth transistor including a first current terminal, a second current terminal and a control terminal, the second current terminal of the fifth transistor coupled to the second current terminal of the first transistor, the first current terminal of the fifth transistor coupled to the first terminal of the third transistor, the control terminal of the fifth transistor coupled to the second current terminal of the fifth transistor;
a sixth transistor including a first current terminal, a second current terminal and a control terminal, the second current terminal of the sixth transistor coupled to the control terminal of the sixth transistor, the first current terminal of the sixth transistor coupled to the first current terminal of the fifth transistor, the control terminal of the sixth transistor coupled to the control terminal of the fifth transistor; and
a current source coupled to the second current terminal of the sixth transistor.

7. The circuit of claim 6, wherein the current terminal of the second transistor is a first current terminal, the second transistor further comprising a second current terminal, the circuit further comprising:
a seventh transistor including a first current terminal, a second current terminal and a control terminal, the second current terminal of the seventh transistor coupled to the second current terminal of the second transistor, the control terminal of the seventh transistor coupled to the control terminal of the sixth transistor, and the first current terminal of the seventh transistor coupled to the first current terminal of the sixth transistor.

8. The circuit of claim 1, wherein the current terminal of the second transistor is a first current terminal, the second transistor further comprising a second current terminal, wherein the input of the amplifier is a first input and the amplifier further comprises a second input, the circuit further comprising:
a first pin coupled to the second current terminal of the second transistor;
a second pin coupled to the second input of the amplifier;
a first resistor comprising a first impedance, including a first terminal and a second terminal, the first terminal of the first resistor coupled to the second current terminal of the first transistor, the second terminal of the first resistor coupled to the first current terminal of the third transistor and to the control terminal of the third transistor; and
a second resistor comprising a second impedance, including a first terminal and a second terminal, the first terminal of the second resistor coupled to the second current terminal of the second transistor and to the first pin, the second terminal of the second resistor coupled to the second terminal of the first resistor, wherein the first impedance of the first resistor is different than the second impedance of the second resistor.

9. The circuit of claim 1, further comprising:
a programmable array including:
a first set of switches including a first terminal and a second terminal, the second terminal of the first set of switches coupled to the second current terminal of the first transistor;
a first set of transistors that each include a first current terminal and a second current terminal, the first current terminal of the first set of transistors coupled to the first current terminal of the first transistor, the second current terminal of the first set of transistors coupled to the first terminal of the first set of switches, respectively;
a second set of switches including a first terminal and a second terminal, the second terminal of the second set of switches coupled to the second current terminal of the first transistor; and
a second set of transistors including a first current terminal and a second current terminal, the first current terminal of the second set of transistors coupled to the first current terminal of the first transistor, the second current terminal of the second set of transistors coupled to the first terminal of the second set of switches, respectively.

10. The circuit of claim 1, wherein the first transistor is a first P-channel metal-oxide semiconductor (PMOS) transistor, the second transistor is a second PMOS transistor, and the third transistor is a first N-channel metal-oxide semiconductor (NMOS) transistor.

11. A circuit, comprising:
an amplifier including an output and an input;
a first transistor including a first current terminal, a second current terminal, and a control terminal, the control terminal of the first transistor coupled to the output of the amplifier;
a second transistor including a current terminal and a control terminal, the current terminal of the second transistor coupled to the first current terminal of the first transistor, the control terminal of the second transistor coupled to the control terminal of the first transistor and to the output of the amplifier;
a set of transistors that each include a first current terminal, a second current terminal, and a control terminal, the first current terminal of the set of transistors coupled to the control terminal of the set of transistors;
a first switch including a first terminal and a second terminal, the first terminal of the first switch coupled to the input of the amplifier, the second terminal of the first switch coupled to the second current terminal of the set of transistors; and
a second switch including a first terminal and a second terminal, the first terminal of the second switch coupled to the second current terminal of the first transistor, the second terminal of the second switch coupled to the second current terminal of the set of transistors.

12. The circuit of claim 11, wherein the set of transistors is a first set of transistors, the circuit comprising:
a second set of transistors that each include a first current terminal and a second current terminal, respectively, the first current terminal of the second set of transistors coupled to the first current terminal of the first set of transistors;
a third switch including a first terminal and a second terminal, the first terminal of the third switch coupled to the input of the amplifier, the second terminal of the third switch coupled to the second current terminal of the second set of transistors; and
a fourth switch including a first terminal and a second terminal, the first terminal of the fourth switch coupled to the second current terminal of the first transistor, the second terminal of the fourth switch coupled to the second current terminal of the second set of transistors, wherein the first set of transistors comprises a first transistor characteristic and the second set of transistors comprises a second transistor characteristic that is different than the first transistor characteristic.

13. The circuit of claim 12, comprising:
a control circuit, coupled to at least one of: the first switch, the second switch, the third switch or the fourth switch, that couples the first set of transistors to the amplifier, to the first transistor and to the second transistor in a test mode of operation from a normal mode of operation.

14. The circuit of claim 11, wherein the current terminal of the second transistor is a first current terminal, the second transistor further comprising a second current terminal, the circuit further comprising:
a first resistor comprising a first impedance, including a first terminal and a second terminal, the first terminal of the first resistor coupled to the second current terminal of the first transistor, the second terminal of the first resistor coupled to the first current terminal of the set of transistors; and
a second resistor comprising a second impedance, including a first terminal and a second terminal, the first terminal of the second resistor coupled to the second current terminal of the second transistor, the second terminal of the second resistor coupled to the second terminal of the first resistor, wherein the first impedance of the first resistor is proportional to the second impedance of the first transistor based on a gain factor of the first transistor and the second transistor.

15. The circuit of claim 11, wherein the current terminal of the second transistor is a first current terminal, the second transistor further comprising a second current terminal, the circuit further comprising:
a current source;
a fifth transistor including a first current terminal, a second current terminal and a control terminal, the second current terminal of the fifth transistor coupled to the second current terminal of the first transistor, the first current terminal of the fifth transistor coupled to the first current terminal of the set of transistors, the control terminal of the fifth transistor coupled to the second current terminal of the fifth transistor;
a sixth transistor including a first current terminal, a second current terminal and a control terminal, the second current terminal of the sixth transistor coupled to the current source and to the control terminal of the sixth transistor, the first current terminal of the sixth transistor coupled to the first current terminal of the fifth transistor, the control terminal of the sixth transistor coupled to the control terminal of the fifth transistor and the control terminal of the sixth transistor; and
a seventh transistor comprising a first current terminal, a second current terminal and a control terminal, the second current terminal of the seventh transistor coupled to the second current terminal of the second transistor, the control terminal of the seventh transistor coupled to the control terminal of the fifth transistor and to the control terminal of the sixth transistor, and the first current terminal of the seventh transistor coupled to the first current terminal of the fifth transistor and to the first current terminal of the sixth transistor.

16. The circuit of claim 11, further comprising:
a programmable array including:
a plurality of transistors including a subset of first transistors and a subset of second transistors, the subset of first transistors including a first current terminal and a second current terminal and the subset of second transistors including a first current terminal and a second current terminal, the first current terminal of the subset of first transistors and the first current terminal of the subset of second transistors are coupled to the first current terminal of the first transistor; and
a plurality of switches including a first terminal and a second terminal, respectively, the first terminal of the plurality of switches coupled to the second current terminal of the subset of first transistors and to the second current terminal of the subset of second transistors, the second terminal of the plurality of switches coupled to the second current terminal of the first transistor and to the first current terminal of the set of transistors.

17. A circuit, comprising:
an amplifier including an output and an input;
a first transistor including a first current terminal, a second current terminal, and a control terminal;
a second transistor including a current terminal and a control terminal, the current terminal of the second transistor coupled to the first current terminal of the first transistor, the control terminal of the second transistor coupled to the control terminal of the first transistor;
a set of transistors including a first current terminal, a second current terminal, and a control terminal, respectively, the first current terminal of the set of transistors coupled to the control terminal of the set of transistors;
a first switch including a first terminal and a second terminal, the first terminal of the first switch coupled to the input of the amplifier, the second terminal of the first switch coupled to the second current terminal of the set of transistors;
at least one component circuitry coupled to the amplifier or the second transistor via a second switch; and
a control circuit, coupled to the first switch and the second switch, wherein the control circuit couples the set of transistors to the amplifier in a test mode of operation and decouples the at least one component circuitry from the amplifier or the second transistor.

18. The circuit of claim 17, wherein the current terminal of the second transistor is a first current terminal, the second transistor comprising a second current terminal, the circuit further comprising:
a Schmitt trigger including a first terminal and a second terminal, the first terminal of the Schmitt trigger coupled to the output of the amplifier, the second terminal of the Schmitt trigger coupled to the second transistor.

19. The circuit of claim 17, comprising:
a first resistor including a first terminal and a second terminal, the first terminal of the first resistor coupled to the first terminal of the first switch, the second terminal of the first resistor coupled to the first current terminal of the set of transistors; and
a second resistor including a first terminal and a second terminal, the first terminal of the second resistor coupled to the second current terminal of the second transistor, the second terminal of the second resistor coupled to the second terminal of the first resistor.

20. The circuit of claim 17, further comprising:
a resistor including a first terminal and a second terminal, the first terminal of the resistor coupled to the second current terminal of the first transistor; and
a Miller capacitor including a first terminal and a second terminal, the first terminal of the Miller capacitor coupled to the control terminal of the first transistor, the second terminal of the Miller capacitor coupled to the second terminal of the resistor.
